(19) United States
(12) Patent Application Publication
(10) Pub. No.: US 2018/0347039 A1
(43) Pub. Date: Dec. 6, 2018

(54) Aerosol Assisted CVD For Industrial Coatings

(71) Applicant: Applied Materials, Inc., Santa Clara, CA (US)

(72) Inventors: Ranga Rao Arnepalli, Andhra Pradesh (IN); Robert Jan Visser, Menlo Park, CA (US); Geetika Bajaj, New Delhi (IN); Prerna Goradia, Vile Parle (W) (IN)

(21) Appl. No.: 15/976,050

(22) Filed: May 10, 2018

Related U.S. Application Data
(60) Provisional application No. 62/515,274, filed on Jun. 5, 2017.

(51) Int. Cl. C23C 16/448; C23C 16/34

(52) U.S. Cl. CPC C23C 16/4486; C23C 16/34

(57) ABSTRACT

Embodiments of the disclosure relate to methods of depositing industrial coating on a substrate or process parts. More particularly, embodiments of the disclosure are directed to methods of depositing metals, metal oxides, metal nitrides and/or metal fluorides on surfaces comprised of metals, ceramics, or organic materials. In some embodiments, a metal-containing precursor can be aerosolized with an organic solvent and exposed to a substrate processing chamber where the organic solvent can be evaporated to adsorb the metal-containing precursor. The adsorbed precursor can be decomposed or reacted to form the metal-containing film.

### CROSS-REFERENCE TO RELATED APPLICATIONS

This application claims priority to U.S. Provisional Application No. 62/515,274, filed Jun. 5, 2017, the entire disclosure of which is hereby incorporated by reference herein.

### FIELD

One or more embodiments of the disclosure relate to methods for depositing industrial coatings on substrates comprised of various materials. More particularly, one or more embodiments of the disclosure relate to methods for depositing industrial coatings on process chambers or process kit components.

### BACKGROUND

Forming films on a substrate by chemical reaction of gases is one of the primary steps in the fabrication of modern semiconductor devices. These deposition processes include chemical vapor deposition (CVD) as well as plasma enhanced chemical vapor deposition (PECVD), which uses plasma in combination with traditional CVD techniques.

Oxidation and reduction reactions are often used to chemically alter the precursors after they have adsorbed to the substrate surface, although any other reaction schemes are also available (e.g. halogenation and nitridation). These reactions typically involve the use of harsh reactants and reaction conditions. The harsh reactants and conditions often lead to shorter life expectancies of many process parts over time as they are prone to suffer corrosion due to the harsh reactants and conditions.

Additionally, many chemical precursors for corrosion inhibiting films and coatings are non-volatile or have low volatility. The low volatility nature of these compounds makes these precursors unsuitable for vapor deposition coating processes.

Therefore, improved methods and apparatus are needed to deposit industrial coatings which reduce the corrosion of process parts.

### SUMMARY

One or more embodiments of the disclosure are directed to a method of depositing a film on a substrate. The method comprises providing a substrate in a process chamber. A metal-containing precursor comprising one or more of Ta, W, Al or Ti and an organic solvent are aerosolized to form an aerosol. The aerosol is flowed into the processing chamber. The organic solvent is evaporated from the aerosol and the metal-containing precursor is adsorbed onto the substrate. The adsorbed metal-containing precursor is reacted with a reactant to form a metal-containing film on the substrate.

Additional embodiments of the disclosure are directed to methods of depositing a metal-containing film on a processing chamber. The method comprises providing a process chamber with one or more process chamber walls. A metal-containing precursor which comprises one or more of Ta, W, Al or Ti and an organic solvent are aerosolized to form an aerosol. The aerosol is flowed into the process chamber. The organic solvent is evaporated from the aerosol and the metal-containing precursor is adsorbed onto the one or more process chamber walls. The adsorbed metal-containing precursor is reacted with a reactant to form a metal-containing film on the processing chamber.

Further embodiments of the disclosure are directed to methods of depositing a film. The method comprises providing a substrate comprised of a metallic material in a process chamber. A precursor solution comprised of a metal-containing precursor comprising one or more of Ta, W, Al, or Ti and a polar organic solvent is provided. The precursor solution is aerosolized with a nebulizer to produce an aerosol. The aerosol is flowed into the process chamber. The organic solvent is evaporated from the aerosol and the metal-containing precursor is adsorbed onto the substrate. The adsorbed metal-containing precursor is reacted with a reactant to form a metal-containing film on the substrate.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process apparatus for aerosol-assisted CVD in accordance with one or more embodiment of the disclosure; and

FIG. 2 illustrates a process flow of an aerosol-assisted process in accordance with one or more embodiment of the disclosure.

### DETAILED DESCRIPTION

Some embodiments of the disclosure provide methods for depositing industrial coatings on corrosion prone process parts. These industrial coatings are metal-based films. These metal-based films can be metals, metal oxides, metal nitrides, or metal fluorides. The protected process parts can include ceramic, metallic or organic materials.

A variation of chemical vapor deposition (CVD) is aerosol-assisted chemical vapor deposition (AACVD). In an AACVD process, precursors are aerosolized and introduced into a substrate processing region of a processing chamber. The aerosolized precursor adsorbs on a substrate to deposit a film. The adsorbed precursor can be co-flowed with a reactant or exposed to thermal conditions to form the final film.

Precursors which are delivered in this way are more likely to produce conformal films than those delivered through traditional CVD spray techniques given that the aerosol spray produces a fine mist which allows for the substrate's features to be saturated from all angles. This feature also helps produce non-line of sight (LOS) coatings where the coated surface is not directly exposed to the precursor source.

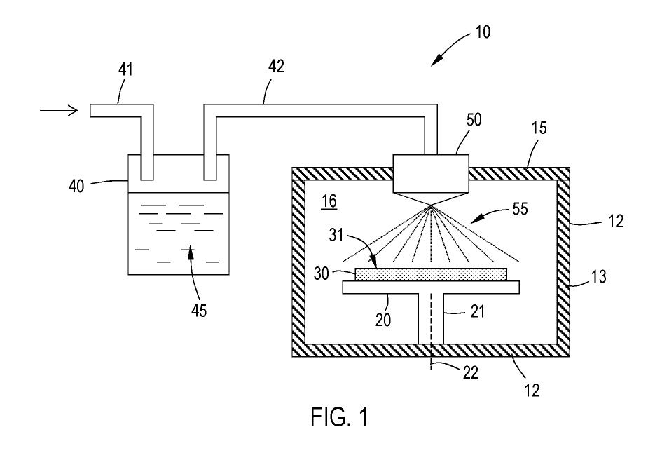

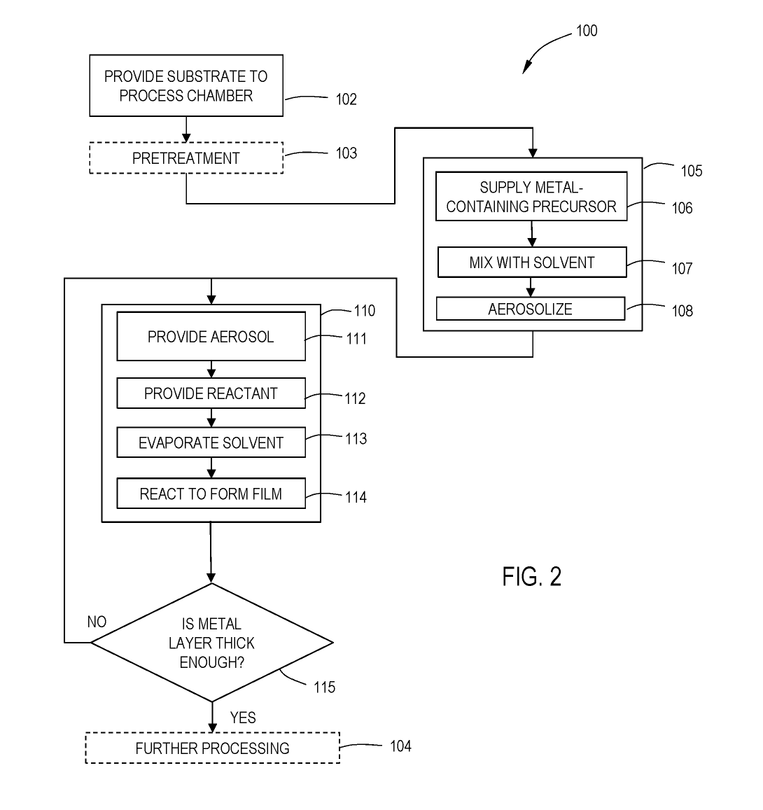

FIG. 1 illustrates an exemplary process apparatus 10 for forming an industrial coating in accordance with one or more embodiment of the disclosure. FIG. 2 depicts an exemplary method 100 for forming an industrial coating comprising a metal-containing film on a substrate in accordance with one or more embodiment of the disclosure.

Referring to FIG. 1, the process apparatus 10 includes a process chamber 12 which may have sides 13, a bottom 14 and a top 15 enclosing a process volume 16. Within the process volume 16, a substrate 30 can be placed on a substrate support 20. The substrate support 20 can include a shaft 21 that is capable of moving the substrate support 20 vertically and rotate the substrate support 20 around the axis 22 of the shaft 21.

An ampoule 40 containing a chemical precursor 45 can be connected to the process apparatus 10. The chemical precursor 45 can be a solid or liquid compound.

A push fluid (or carrier fluid) is flowed through an inlet 41 of the ampoule to draw precursor molecules from the precursor 45. The push fluid of some embodiments is an organic solvent or mixture of organic solvent and miscible or immiscible solvents. The push fluid may include surfactants or solubilizing agents.

The push fluid containing the precursor molecules flows from the ampoule 40 through outlet line 42 to an aerosolizer 50 connected to the process chamber 12. The aerosolizer 50 can be any suitable component that can create an aerosol 55 from the push fluid by evaporating the push fluid and forming a spray of precursor molecules. In the embodiment illustrated in FIG. 1, the aerosolizer 50 is connected to or an integral part of the top 15 of the processing chamber 12. However, it will be understood by those skilled in the art that the aerosolizer 50 can be a separate component from the processing chamber 12 and can be configured to provide an aerosol 55 from the top, bottom or sides of the processing chamber 12.

Referring to FIG. 2, the method 100 generally begins at 102, where a substrate 30 having a surface 31 upon which the industrial coating is to be formed is provided and placed into a processing chamber 12. A “substrate surface”, as used herein, refers to any portion of a substrate or portion of a material surface formed on a substrate upon which film processing is performed. For example, a substrate surface on which processing can be performed includes materials such as silicon, silicon oxide, silicon nitride, doped silicon, germanium, gallium arsenide, glass, ceramics, sapphire, and any other materials such as metals, metal nitrides, metal alloys, and other conductive materials, depending on the application. Substrates include, without limitation, semiconductor wafers and process parts which may be comprised of metal, ceramic or organic materials. Substrates may be exposed to a pretreatment process 103 or a posttreatment process to polish, etch, reduce, oxidize, hydroxylate, anneal, UV cure, e-beam cure and/or bake the substrate surface. In addition to substrate processing directly on the surface of the substrate itself, in the present disclosure, any of the substrate processing steps disclosed may also be performed on an underlayer formed on the substrate as disclosed in more detail below, and the term “substrate surface” is intended to include such underlayer as the context indicates. Thus for example, where a layer or partial layer has been deposited onto or etched from a substrate surface, the exposed surface of the newly deposited or etched layer becomes the substrate surface. Substrates may have various dimensions, such as 200 mm or 300 mm diameter wafers, as well as, rectangular or square panes. In some embodiments, the substrate comprises a rigid discrete material. In some embodiments, the substrate is a process part used in a processing chamber. In some embodiments, the substrate 30 is process chamber component or process kit component with an irregular shape. For example, the substrate 30 of some embodiments is an edge ring, pedestal, confinement ring or process chamber wall.

As used in this specification and the appended claims, the terms “reactive compound”, “reactive gas”, “reactive species”, “precursor”, “process gas”, “deposition gas”, “metal source”, and the like are used interchangeably to mean a substance with a species capable of reacting with the substrate surface or a material on the substrate surface. The substrate, or portion of the substrate, is exposed to the metal-containing precursor, which is introduced into a reaction zone of a processing chamber. In some embodiments, the metal-containing precursor is introduced in a reaction zone of a processing chamber as an aerosolized spray.

Next, aerosolization 105 of a metal-containing precursor provides an aerosol for deposition. Aerosolization 105 can include several sub-processes in any order. The embodiment illustrated in FIG. 2 is merely representative of one possible aerosolization process and should not be taken as limiting the scope of the disclosure. A metal-containing precursor is supplied at 106 and mixed with a solvent at 107 and an aerosol is formed at 108. In one or more embodiment, aerosolization produces fine droplets of a metal-containing precursor. The droplets may range in size from a number average particle size diameter of about 10 nm to a number average particle size diameter of about 2 μm. In an embodiment, droplets having a number average particle size diameter of 1 μm or less result in an aerosol mist that allows for deposition as non-line of sign coatings for coating ceramics and metals. In one or more embodiments, the aerosolized droplets range in size from a number average particle size diameter of about 10 nm to a number average particle size diameter of about 1 μm. In one or more embodiments, the aerosolized droplets size can be measures by a scanning mobility particle sizer (SMPS), which is an analytical instrument that measures the size and number concentration of aerosol particles with diameters from 2.5 nm to 1000 nm. A SMPS employa a continuous, fast-scanning technique to provide high-resolution measurements. SMPS products number average particle size.

The metal-containing precursor can be any suitable metal-containing species depending on, for example, the species to be coated on the substrate or the process conditions (e.g., temperature). In some embodiments, the metal-containing precursor comprises one or more of tantalum (Ta), tungsten (W), aluminum (Al), or titanium (Ti). In one or more embodiments, the metal-containing precursor comprises one or more of tantalum (Ta), tungsten (W), aluminum (Al), titanium (Ti), or a rare earth metal. As used herein, the term “rare earth metal” refers to a set of chemical elements including the lanthanides, as well as scandium and yttrium. Specifically, in one or more embodiments, the rare earth metal is selected from cerium (Ce), dysprosium (Dy), erbium (Er), europium (Er), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbrium (Yb), and yttrium (Y).

In some embodiments, the metal-containing precursor comprises more than one metal-containing species. In some embodiments, the metal-containing species contain the same metal. For example, the metal-containing precursor of some embodiments comprises two different tantalum species. In some embodiments, the metal-containing species contain different metals. For example, the metal-containing precursor of some embodiments comprises a tantalum precursor and a titanium precursor.

In some embodiments, the metal-containing precursor consists essentially of tantalum-containing compounds. In some embodiments, the metal-containing precursor consists essentially of tungsten-containing compounds. In some embodiments, the metal-containing precursor consists essentially of aluminum-containing compounds. In some embodiments, the metal-containing precursor consists essentially of titanium-containing compounds. As used in this regard, the term “consists essentially of” means that the metal precursor is greater than or equal to about 95%, 98% or 99% of the stated metal on a molecular basis. For example, the sum of all tantalum containing reactive species as a percentage of the total amount of reactive metal species present in the precursor.

The metal-containing precursor is mixed with a suitable solvent at 107. The solvent of some embodiments comprises an organic solvent which solubilizes the metal-containing precursor. In some embodiments, the organic solvent comprises a polar solvent. The polar solvent can be protic or aprotic. In some embodiments, the polar solvent is protic and comprises one or more of water, alcohols, formic acid, hydrogen fluoride (HF), or ammonia (NH₃). In some embodiments, the polar solvent is aprotic and comprises one or more of N-methylpyrrolidone (NMP), tetrahydrofuran (THF), ethyl acetate (EtOAc), acetone, dimethylformamide (DMF), acetonitrile, dimethylsulfoxide (DMSO), or propylene carbonate. In some embodiments, the polar solvent consists essentially of isopropyl alcohol. In some embodiments, the polar solvent consists essentially of tetrahydrofuran (THF). As used in this regard, the term “consists essentially of” means that the polar solvent is greater than or equal to about 95%, 98% or 99% of the stated material on a weight basis.

The combination of the metal-containing precursor and the organic solvent may be referred to as condensed matter. In general, condensed matter consists of atoms/molecules which are constantly under the influence of the forces imparted by neighboring atoms/molecules and may be defined as matter having essentially no or no mean free path (i.e., the average distance that a molecule can travel between collisions with other molecules).

Next, at 108, an aerosol is formed from the condensed matter with a nebulizer. The metal-containing precursors do not need to be volatile to generate the aerosol droplets. In some embodiments, the aerosol may be formed using an ultrasonic humidifier type nebulizer. The ultrasonic humidifier has a piezoelectric transducer that can be operated at one or more frequencies. The nebulizer, regardless of type or method of operation, generates aerosol droplets which are carried into the reaction chamber (substrate processing region) using a carrier gas or push fluid. As used in this regard, the terms “carrier gas”, “carrier fluid”, “push gas”, “push fluid” and the like, refers to a fluid (either gas or liquid) that can move a precursor molecule from one location to a aerosolizer. For example, a push fluid can be a liquid that moves molecules from a solid precursor in an ampoule to an aerosolizer. In some embodiments, a push gas moves molecules from a liquid or solid precursor in an ampoule to an aerosolizer.

In some embodiments, the carrier gas comprises nitrogen (N₂) or argon (Ar). The carrier gas may be inert and not form covalent chemical bonds with the condensed matter nor with the substrate. An inline mechanical pump (not shown) connected with the aerosol generator can also be used to push the carrier gas and aerosol droplets towards the substrate.

In one or more embodiment, the aerosol droplets range in size from an average diameter of about 10 nm to an average diameter of about 2 μm. In one or more embodiments, the aerosol droplets range in size from an average diameter of about 10 nm to an average diameter of about 1 μm.

The aerosol droplets may pass through conduit(s) which are heated to prevent condensation or to promote reaction with a substrate after the aerosol droplets enter the substrate processing region. The substrate processing region resides within a substrate processing chamber and may be a vacuum chamber which is evacuated of atmospheric gases prior to delivery of the aerosol into the substrate processing region. The substrate processing region may be sealed from the external atmosphere and may be operated at much lower than atmospheric pressure to evacuate the atmospheric gases in select embodiments. In some embodiments, the processing chamber may be allowed to remain at or near atmospheric pressure.

Film formation 110 comprises several processes or sub-processes shown in an exemplary order. However, those skilled in the art will recognize that the order of processes shown in FIG. 2 is merely one possible method configuration and should not be taken as limiting the scope of the disclosure. At 111, the condensed matter, in the form of an aerosol spray, is flowed into the processing chamber with the substrate. A reactant can be supplied to the processing chamber at 112. The condensed matter and the reactant can be mixed prior to flowing into the processing chamber or can remain separate until both enter the processing chamber. In some embodiments, the condensed matter and the reactant do not mix in the gas phase and are exposed to the substrate sequentially.

The organic solvent from the aerosol is evaporated at 113 and the metal-containing precursor can adsorb onto the substrate surface. The organic solvent may be evaporated by any suitable means, but evaporation may be promoted through, for example, the elevated temperature of the substrate relative to the processing chamber, or the decreased pressure of the processing chamber relative to the conduit(s) which provide(s) the aerosol.

The adsorbed metal-containing precursor can be reacted with a reactant to form a metal-containing film on the substrate at 114. The metal-containing precursor and the reactant can both be selected to impact the composition of the resulting film. For example, when the reactant is hydrogen, a metal film may be formed, but when the reactant is ammonia or hydrazine, a metal nitride film may be formed.

In some embodiments, the reactant comprises one or more of NH₃, hydrazine, hydrazine derivatives, or plasmas thereof. In some embodiments, the reactant comprises one or more of NO or NO₂. In some embodiments, the reactant is selected to deposit a metal nitride on the substrate. In some embodiments, the reactant comprises one or more of O₂, O₃, H₂O, or plasmas thereof. In one or more embodiments, the reactant is selected to deposit a metal oxide on the substrate. In some embodiments, the reactant comprises one or more fluoride compounds (e.g. HF). In one or more embodiments, the reactant is selected to deposit a metal fluoride on the substrate.

In some embodiments, there is no reactant provided at 112. Without a reactant, a thermal decomposition process can occur in which the metal precursor adsorbs onto the substrate surface and thermally decomposes to the metal or metal-containing species to form the film.

Next, at decision point 115, it is determined whether the metal-containing film has achieved a predetermined thickness. If the predetermined thickness has not been achieved, the method 100 returns to film formation 110 to continue forming the metal-containing film until the predetermined thickness is reached. Once the predetermined thickness has been reached, the method 100 can either end or proceed to 104 for optional further processing (e.g., bulk deposition of metal film or other protectant or post-treatment). In some embodiments, the bulk deposition process may be a CVD process. Upon completion of deposition of the metal-containing film to a predetermined thickness, the method 100 generally ends and the substrate can proceed for any further processing. For example in some embodiments, the metal-containing layer may be deposited to form a total layer thickness of about 10 to about 10,000 Å, or in some embodiments, about 10 to about 1000 Å, or in some embodiments, about 500 to about 5,000 Å.

A “pulse” or “dose” as used herein is intended to refer to a quantity of a process gas, carrier gas or aerosol spray that is intermittently or non-continuously introduced into the process chamber. The quantity of a particular compound within each pulse may vary over time, depending on the duration of the pulse. A particular process gas may include a single compound (e.g. a reactant) or a mixture/combination of two or more compounds (e.g. a metal-containing precursor and a solvent).

The durations for each pulse/dose are variable and may be adjusted to accommodate, for example, the volume capacity of the processing chamber or the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/react onto substantially the entire surface of the substrate and form a layer of a process gas component thereon.

The period of time that the substrate is exposed to the process gas may be any suitable amount of time necessary to allow the metal source to form an adequate nucleation layer atop the substrate surfaces. For example, the process gas may be flowed into the process chamber for a period of about 1 second to about 500 seconds.

In some embodiments, a carrier gas may additionally be provided to the process chamber at the same time as the aerosol spray. The carrier gas may be mixed with the metal-containing precursor and solvent (e.g., as a diluent gas) or separately and can be pulsed or of a constant flow. In some embodiments, the inert gas is flowed into the processing chamber at a constant flow in the range of about 1 to about 10000 sccm. The inert gas may be any inert gas, for example, such as argon, helium, neon, combinations thereof, or the like.

In addition to the foregoing, additional process parameters may be regulated while exposing the substrate to the metal-containing precursor, solvent and/or reactant. For example, in some embodiments, the process chamber may be maintained at a certain pressure or at a certain temperature to facilitate the deposition of the metal-containing film.

After a predetermined amount of metal-containing film has been deposited, a posttreatment reaction may occur. Suitable reactants for post treatment include, but are not limited to, H₂, NH₃, hydrazine, hydrazine derivatives and other co-reactants to make MₓN_{y} films. Suitable reactants may also include, but are not limited to, O₂, O₃, water and other oxygen based co-reactants to make MₓO_{y} films. Post treatments may also be combined to produce oxynitride metal surfaces. Other suitable reactants for post treatment include a compound selected to form a metal silicide, metal silicate, metal carbide, metal carbonitride, metal oxycarbide, metal oxycarbonitride, or a metal film including one or more of O, N, C, Si or B. Plasma treatments of a reactant as a post-treatment may also be used.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a film, the method comprising:
providing a substrate in a process chamber;
aerosolizing a metal-containing precursor with an organic solvent to form an aerosol, the metal-containing precursor comprising one or more of Ta, W, Al, Ti, Ce, Dy, Er, Er, Gd, Ho, La, Lu, Nd, Pr, Pm, Sm, Sc, Tb, Tm, Yb, or Y;
flowing the aerosol into the processing chamber;
evaporating the organic solvent from the aerosol and adsorbing the metal-containing precursor onto the substrate; and
reacting the adsorbed metal-containing precursor with a reactant to form a metal-containing film on the substrate.

2. The method of claim 1, wherein the substrate is selected from a ceramic material, a metallic material, and an organic material.

3. The method of claim 1, wherein the reactant is selected from the group consisting of NH₃, hydrazine, hydrazine derivatives, NO, NO₂, O₂, O₃, H₂O, HF, combinations thereof, or plasmas thereof.

4. The method of claim 1, wherein the aerosol comprises droplets having a number average particle size diameter in a range of about 10 nm to about 2 μm.

5. The method of claim 4, wherein the aerosol comprises droplets having a number average particle size diameter in a range of about 10 nm to about 1 μm.

6. The method of claim 1, wherein the metal-containing precursor consists essentially of tantalum-containing compounds.

7. The method of claim 1, wherein the metal-containing precursor consists essentially of tungsten-containing compounds.

8. The method of claim 1, wherein the metal-containing precursor consists essentially of aluminum-containing compounds.

9. The method of claim 1, wherein the metal-containing precursor consists essentially of titanium-containing compounds.

10. The method of claim 1, wherein the organic solvent comprises a polar solvent.

11. The method of claim 10, wherein the organic solvent is selected from the group consisting of water, alcohols, formic acid, hydrogen fluoride, ammonia, N-methylpyrrolidone, ethyl acetate, acetone, dimethylformamide (DMF), acetonitrile, dimethylsulfoxide (DMSO), propylene carbonate, isopropyl alcohol, or tetrahydrofuran (THF).

12. The method of claim 1, wherein the metal-containing precursor and the organic solvent are aerosolized with a nebulizer.

13. The method of claim 1, wherein the process chamber is maintained under vacuum.

14. The method claim 1, wherein the process chamber is maintained at about atmospheric pressure.

15. The method of claim 1, wherein the metal-containing film comprises one or more of a metal oxide, a metal fluoride, or a metal nitride.

16. The method of claim 15, wherein the metal-containing film consists essentially of a metal oxide.

17. The method of claim 15, wherein the metal-containing film consists essentially of a metal fluoride.

18. The method of claim 15, wherein the metal-containing film consists essentially of a metal nitride.

19. A method of depositing a film, the method comprising:
providing a process chamber with one or more process chamber walls;
aerosolizing a metal-containing precursor with an organic solvent to form an aerosol, the metal-containing precursor comprising one or more of Ta, W, Al, Ti, Ce, Dy, Er, Er, Gd, Ho, La, Lu, Nd, Pr, Pm, Sm, Sc, Tb, Tm, Yb, or Y;
flowing the aerosol into the process chamber;
evaporating the organic solvent from the aerosol and adsorbing the metal-containing precursor onto the one or more process chamber walls; and
reacting the adsorbed metal-containing precursor with a reactant to form a metal-containing film on the processing chamber.

20. A method of depositing a film, the method comprising:
providing a substrate comprised of a metallic material in a process chamber;
providing a precursor solution comprised of a metal-containing precursor and a polar organic solvent, the metal-containing precursor comprising one or more of Ta, W, Al, or Ti;
aerosolizing the precursor solution with a nebulizer to produce an aerosol;
flowing the aerosol into the process chamber;
evaporating the organic solvent from the aerosol and adsorbing the metal-containing precursor onto the substrate; and
reacting the adsorbed metal-containing precursor with a reactant to form a metal-containing film on the substrate.
